(19) United States
(12) Patent Application Publication
(10) Pub. No.: US 2011/0227230 A1
(43) Pub. Date: Sep. 22, 2011

(54) THROUGH-SILICON VIA FABRICATION WITH ETCH STOP FILM

(75) Inventors: Shiqun Gu, San Diego, CA (US); Yiming Li, San Dieog, CA (US); Urmi Ray, San Diego, CA (US)

(73) Assignee: QUALCOMM INCORPORATED, San Diego, CA (US)

(21) Appl. No.: 12/727,750

(22) Filed: Mar. 19, 2010

(51) Int. Cl. H01L 23/48; H01L 21/768

(52) U.S. Cl. 257/773; 438/675; 257/E21.585; 257/E23.011

(57) ABSTRACT

For a semiconductor wafer substrate having an inter layer dielectric, a through-silicon via may be formed in the substrate by first depositing an etch stop film on top of the inter layer dielectric, followed by etching an opening through the etch stop film, the interlayer dielectric, and into the substrate. A dielectric liner is then deposited over the etch stop film and into the opening. For some embodiments, the dielectric liner may be etched away except for those portions adhering to the sidewall of the opening. Then a conductive material may be deposited into the opening and on the etch stop film. The excess conductive material may then be removed, and for some embodiments the etch stop film may also be removed.

### FIELD

The present invention relates to semiconductor process technology, and more particularly, to fabricating through-silicon vias.

### BACKGROUND

A through-silicon via is a vertical electrical connection passing completely through a silicon die or wafer. A through-silicon via in a die connects a metal layer or component on the active side of the die to a pad or component on the other side of the die. In one application, two or more dies having integrated circuits may be stacked vertically, where through-silicon vias electrically connect the integrated circuits. This application is referred to as 3D packaging, or chip stacking.

FIG. 1 illustrates a conventional process for forming a through-silicon via, where the process sequence is illustrated by five plan views (not drawn to scale) designated by the letters A through E. The plan view designated by the letter A shows a slice of a wafer with a substrate 102 and a transistor formed on it, where the portions of the transistor visible in the plan view are the gate 104, and the side spacers 106 and 108. The gate oxide underneath the gate 104 is not shown in the plan view for ease of illustration. Formed on top of the substrate 102 is a contact dielectric layer 110, often referred to as an inter-layer dielectric (ILD), and usually comprised of silicon dioxide. A contact 112 provides electrical connection to the gate 104. Although not shown in FIG. 1, later in the process a metal layer is formed above the contact dielectric layer 110 to provide electrical connection among various circuit components formed on the substrate 102. For ease of illustration, only one circuit component (the transistor comprising the gate 104) is shown in the plan view.

In the plan view designated by the letter B, an opening 114 has been etched into the contact dielectric layer 110 and the substrate 102 to begin the process of forming a through-silicon via. In practice, the etching will not necessarily produce a vertical sidewall, as illustrated in simplified fashion in the plan view of B in FIG. 1.

In the plan view designated by the letter C, a liner dielectric 116 has been formed over the contact dielectric layer 110 and into the opening 114. The liner dielectric 116 electrically isolates the through-silicon via from the substrate 102. Depending upon the material used, the liner dielectric 116 may also improve adherence of conductive material to be deposited into the opening 114. In many applications, the liner dielectric 116 may comprise silicon nitride or silicon dioxide. Note that the plan view designated by the letter C shows that the thickness of the dielectric liner 116 at the bottom of the opening 114 is larger than along the sidewall of the opening 114. Again, for ease of illustration, the sidewall of the dielectric liner 116 are shown to be vertical, although in practice this may not be the case.

In the plan view designated by the letter D, a conductive material 118 has been deposited into the opening 114 and on top of the dielectric liner 116. The conductive material may be copper or tungsten, for example. In the plan view designated by the letter E, the portions of the dielectric liner 116 and the conductive material 118 directly above the contact dielectric layer 110 have been removed by polishing, resulting in the through-silicon via 120 comprising the remaining portions of the conductive material 118 and the dielectric liner 116 inside the opening 114.

The thickness of the contact dielectric layer 110 at the beginning of the process (for example the plan view designated by the letter A) is about 0.15 μm, whereas the thickness of the dielectric liner 116 above the contact dielectric layer 110 is usually larger than 0.3 μm, and the thickness of the conductive material 118 directly above the contact dielectric layer 110 is about 3 to 5 μm. Because the chemical composition of the dielectric liner 116 is close to that of the contact dielectric layer 110, and because there is variation in the polishing process, polishing down the conductive material 118 and the dielectric liner 116 to form the through-silicon via 120 often results in removal of a significant portion of the contact dielectric layer 110. This removal is indicated by showing the thickness of the contact dielectric layer 110 in the plan view designated by the letter E as being less than the thickness of the contact dielectric layer 110 in the plan views designated by the letters A through D.

Removing too much of the contact dielectric layer 110 may result in various unwanted circuit performance issues. For example, there may be an unwanted increase in the capacitance between a first metal layer and transistor gates or active areas, there may be shorts between such a metal layer and various transistor gates, there may be contact integrity degradation, and there may be resistance variations among various interconnects. A process whereby through-silicon vias may be formed in a wafer without significant removal of the contact dielectric layer would be of utility.

### SUMMARY

In an embodiment, to form a through-silicon via in a substrate having a contact dielectric layer, an etch stop film is formed so that the contact dielectric layer is disposed between the substrate and the etch stop film. An opening is then etched through the etch stop film, the contact dielectric layer, and into the substrate.

In addition, a dielectric liner is then formed on the etch stop film, and on the sidewall and the bottom of the opening. The dielectric liner is removed from the etch stop film and at the bottom of the opening. In addition, the etch stop film may be removed.

In another embodiment, a substrate has an etch stop film and a contact dielectric layer disposed between the substrate and the etch stop film. A through-silicon via is through the contact dielectric layer and the etch stop film, and reaches into the substrate. The via includes a dielectric liner on its sidewall, and a conductor in contact with the dielectric liner and the substrate at the bottom of the via.

### BRIEF DESCRIPTION OF THE DRAWINGS

FIG. 1 illustrates a conventional process for fabricating a through-silicon via.

FIG. 2 illustrates a process for fabricating a through-silicon via using an etch stop film.

FIG. 3 illustrates a flow process for fabricating a through-silicon via using an etch stop film.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

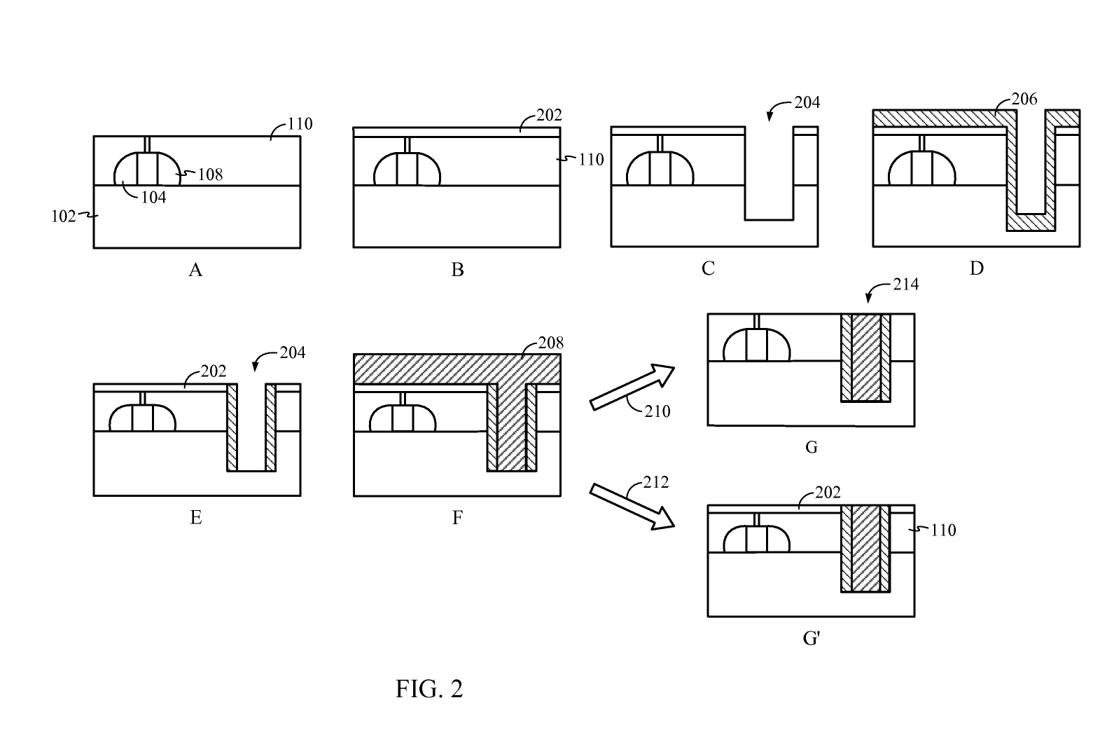

FIG. 2 illustrates a process for forming a through-silicon via, where the process sequence is illustrated by plan views (not drawn to scale) designated by the letters A through F, and followed by either G or G′. That is, from the plan view designated by the letter F, the plan view designated by the letter G may follow, or the plan view designated by the letter G′.

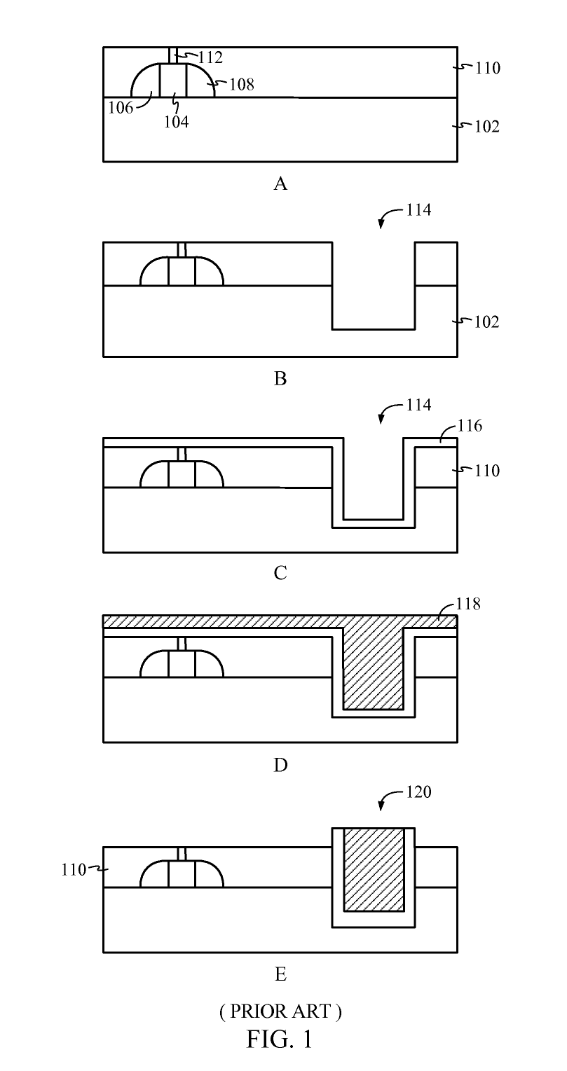

The plan view in FIG. 2 designated by the letter A is the same as the plan view in FIG. 1 designated by the letter A. In the plan view in FIG. 2 designated by the letter B, an etch stop film 202 has been applied on top of the contact dielectric layer 110. The etch stop film 202 may have a thickness less than that of the contact dielectric layer 110. For example, for some embodiments, the etch stop film 202 may have a thickness of 50±5 nm. The etch stop film 202 has a different composition than the contact dielectric layer 110, and provides selectivity when etching so that portions of a layer deposited on the etch stop film 202 may be selectively etched away without etching away the etch stop film 202.

For some embodiments, the etch stop film 202 may be an insulator, and may have a dielectric constant higher than that of the contact dielectric layer 110. For some embodiments, the etch stop film 202 may comprise silicon nitride, SiNi, or silicon carbide, SiC, for example. Etch stop films are well known to practitioners in the art of semiconductor process fabrication. For example, one such low-k (low dielectric constant) etch stop film is marketed under the name BLOk™, or variants thereof, a trademark of Applied Materials, Inc., a Delaware Corporation headquartered in Santa Clara, Calif. For some embodiments, the etch stop film 202 may be a metal.

In the plan view designated by the letter C, an opening 204 has been etched through the etch stop film 202, the contact dielectric layer 110, and into the substrate 102. This may be performed by depositing another etch stop film on top of etch stop film 202, but of different composition than that of etch stop film 202, so that selective etching may be performed. A mask may then be used with this other etch stop film so that a pattern for opening 204 may be fabricated, following by etching to provide opening 204. This other etch stop film may then be selectively stripped away, leaving etch stop film 202 as shown.

In the plan view designated by the letter D, a dielectric liner 206 has been deposited over the etch stop film 202, and on the sidewall and the bottom of the opening 204. The sidewall of the opening 204 may be viewed as the approximately vertical surfaces of the substrate 102, the contact dielectric layer 110, and the etch stop film 202 formed by the opening 204. The bottom of the opening 204 may be viewed as the remaining surface of the substrate 102 formed by the opening 204. The dielectric liner 206 may comprise silicon dioxide or silicon nitride, for example, but should have a different composition than the etch stop film 202.

In the plan view designated by the letter E, reactive ion etching (RIE) has been used to remove portions of the dielectric liner 206 that covered the top of the etch stop film 202 and the bottom of the opening 204. The remaining portion of the dielectric liner 206 covers the sidewall of the opening 204.

In the plan view designated by the letter F, a conductive material 208 has been deposited into the opening 204 and on top of the etch stop film 202. The conductive material 208 may be copper or tungsten, for example. Because RIE has removed the portion of the dielectric liner that had covered the bottom of the opening 204, it is expected that applying the conductive material 208 by electroplating may be improved because the portion of the substrate 102 at the bottom of the opening 204 can make electrical contact with the deposited conductive material 208.

The arrows 210 and 212 indicate that either of the plan views designated by the letters G and G′ may follow the plan view designated by the letter F. In the plan view designated by the letter G, chemical-mechanical polishing (CMP) has been used to remove the portion of the conductive material 208 above the etch stop film 202, as well as the etch stop film 202. The result is the silicon-through via 214 comprising the remaining portion of the conductive material 208 and the remaining portion of the dielectric liner 206 left on the sidewall of the opening 204. Because the thickness of the etch stop film 202 (e.g., 50±5 nm) is relatively small compared to the thickness of the contact dielectric layer 110, it is expected that there may only be approximately an over-polishing of 10 nm, so that only a relatively small amount of the thickness of the contact dielectric layer 110 may be lost during removal of the etch stop film 202.

In the plan view designated by the letter G′, for those embodiments in which the etch stop film 202 is an insulator, chemical-mechanical polishing (CMP) has been used to remove the portion of the conductive material 208 above the etch stop film 202, but the etch stop film 202, or at least a portion thereof, has been left on the contact dielectric layer 110. Leaving an etch stop film on the contact dielectric layer 110 may have utility if a metal layer is to be added over the contact dielectric layer 110. For example, later in the processing flow, a low-k ILD may be added above the etch stop film 202, and portions of the low-k ILD where metal is to be deposited may be etched away. The exposed portions of the etch stop film 202 after etching of the low-k ILD may then be selectively etched away so that the metal may then be deposited.

For some embodiments, etching away the dielectric liner 206 as indicated in the plan view E in FIG. 2 need not be done, where after the conductive material 208 has been deposited, CMP may be used to remove the excess conductive material 208 and the dielectric liner 206 on the etch stop film 202. But for such embodiments, note that the bottom of the opening 204 may still be covered with the dielectric liner 206, so that the final result will not look like the plan views G or G′.

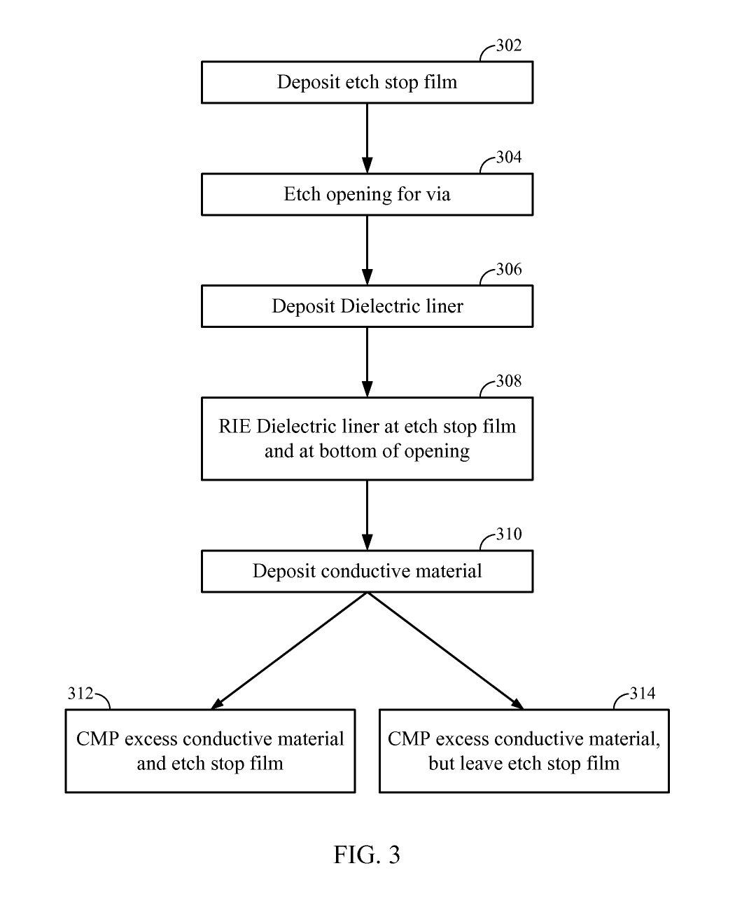

FIG. 3 illustrates a flow diagram for fabricating a through-silicon via, as described with respect to the embodiment of FIG. 2. An etch stop film is deposited over a dielectric layer (302), after which an opening is made for the through-silicon via (304). A dielectric liner is deposited (306), and RIE is used to remove the dielectric liner at the etch stop film and at the bottom of the opening (308). A conductive material is deposited (310), after which CMP may be used to remove the excess conductive material and the etch stop film (312), or CMP may be used to remove the excess conductive material, but where the etch stop film is not completely removed (314).

As discussed previously with respect to FIG. 2, for some embodiments, etching away the dielectric liner 206 as indicated in the block 308 of FIG. 3 need not be done, so that after the conductive material 208 has been deposited, CMP may be used to remove the excess conductive material 208 and the dielectric liner 206 on the etch stop film 202.

In most applications, the substrate 102 may be silicon. However, a substrate comprising other types of material may be used. Accordingly, the term through-silicon via is not meant to imply that a substrate containing the through-silicon via is necessarily silicon.

Various modifications may be made to the described embodiments without departing from the scope of the invention as claimed below. For example, referring to FIG. 2, another layer, such as for example a sacrificial layer, may be deposited on the contact dielectric layer 110 before depositing etch stop film 202, which then may be removed to arrive at the plan view G. For such embodiments, etch stop film 110 is not necessarily deposited directly on top of the contact dielectric layer 110.

What is claimed is:

1. A method to form a via in a substrate having a contact dielectric layer, the method comprising:
forming an etch stop film so that the contact dielectric layer is disposed between the substrate and the etch stop film; and
etching an opening through the etch stop film, the contact dielectric layer, and into the substrate, the opening having a sidewall and a bottom in the substrate.

2. The method as set forth in claim 1, wherein the etch stop film is formed on the contact dielectric layer.

3. The method as set forth in claim 1, further comprising:
depositing a dielectric liner on the etch stop film, and on the sidewall and the bottom of the opening.

4. The method as set forth in claim 3, further comprising reactive ion etching to remove the dielectric liner at the bottom of the opening and on the etch stop film.

5. The method as set forth in claim 4, further comprising forming a conductive material in contact with the bottom of the opening and the dielectric liner.

6. The method as set forth in claim 5, wherein forming the conductive material comprises electroplating.

7. The method as set forth in claim 5, further comprising removing a portion of the conductive material on the etch stop film.

8. The method as set forth in claim 7, further comprising removing the etch stop film.

9. The method as set forth in claim 3, further comprising forming a conductive material in contact with the dielectric liner.

10. The method as set forth in claim 9, further comprising removing a portion of the conductive material on the dielectric liner.

11. The method as set forth in claim 10, further comprising removing the dielectric liner on the etch stop film.

12. The method as set forth in claim 11, further comprising removing the etch stop film.

13. The method as set forth in claim 1, wherein the etch stop film is chosen from the set consisting of an insulator and a metal.

14. The method as set forth in claim 1, the etch stop film having a dielectric constant, and the contact dielectric layer having a dielectric constant less than the dielectric constant of the etch stop film.

15. An article of manufacture comprising:
a substrate;
an etch stop film;
a contact dielectric layer disposed between the substrate and the etch stop film;
a via formed into the substrate, and through the contact dielectric layer and the etch stop film; the via having a sidewall and comprising a dielectric liner formed on the sidewall; and
a conductor formed in the via and in contact with the dielectric liner; the via having a bottom, the conductor in contact with the substrate at the bottom of the via.

16. The article of manufacture as set forth in claim 15, wherein the substrate comprises silicon.
